(19) United States
(12) Patent Application Publication
(10) Pub. No.: US 2014/0118921 A1
(43) Pub. Date: May 1, 2014

(54) MOUNTING APPARATUS FOR HARD DISK DRIVE

(71) Applicant: CHIH-HAO LIN, New Taipei (TW)

(72) Inventor: CHIH-HAO LIN, New Taipei (TW)

(21) Appl. No.: 13/680,122

(22) Filed: Nov. 19, 2012

(30) Foreign Application Priority Data
Oct. 29, 2012 (TW) 101139881

(51) Int. Cl. G06F 1/16; H05K 7/00

(52) U.S. Cl. CPC G06F 1/16; H05K 7/00
USPC 361/679.33; 361/679.01

(57) ABSTRACT

An electronic device includes a hard disk drive with a first and a second mounting poles and a mounting apparatus. The mounting apparatus includes a bracket and a first positioning member. The bracket includes a first side plate. A first latching slot is defined in the first side plate. The first latching slot includes an opening extending through a bottom side of the first side plate, a notch, and a guiding portion connected between the opening and the notch. The first positioning member is installed to the bracket and includes a resilient first engaging piece. The first mounting pole is inserted into the first latching slot from the opening, to abut the first engaging piece and deform the first engaging piece, until the first mounting pole is received in the notch. The first positioning member is moved, to allow the first engaging piece to abut the first mounting pole.

### BACKGROUND

1. Technical Field

The present disclosure relates to an apparatus for mounting a hard disk drive.

2. Description of Related Art

In a typical computer, a hard disk drive (HDD) is needed to store information. The HDD is usually mounted in a bracket mounted in a rack of the computer. The HDD is directly inserted into the bracket, and a large number of screws extend through sidewalls of the bracket to fix the HDD to the bracket. However, mounting or removing the HDD to or from the bracket requires a tool to fasten or release the screws. Thus, the assembly and disassembly of the HDD are not only time-consuming but also laborious.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an isometric, exploded view of an exemplary embodiment of an electronic device, wherein the electronic device includes two first positioning members, two second positioning members, and a hard disk drive (HDD).

FIG. 2 is an inverted, enlarged view of one of the first positioning members of FIG. 1.

FIG. 3 is an inverted, enlarged view of one of the second positioning members of FIG. 1.

FIG. 4 is a partially assembled, isometric view of FIG. 1.

FIGS. 5-6 are isometric views showing the process of assembling the HDD of FIG. 1.

### DETAILED DESCRIPTION

The present disclosure, including the accompanying drawings, is illustrated by way of examples and not by way of limitation. It should be noted that references to “an” or “one” embodiment in this disclosure are not necessarily to the same embodiment, and such references mean at least one.

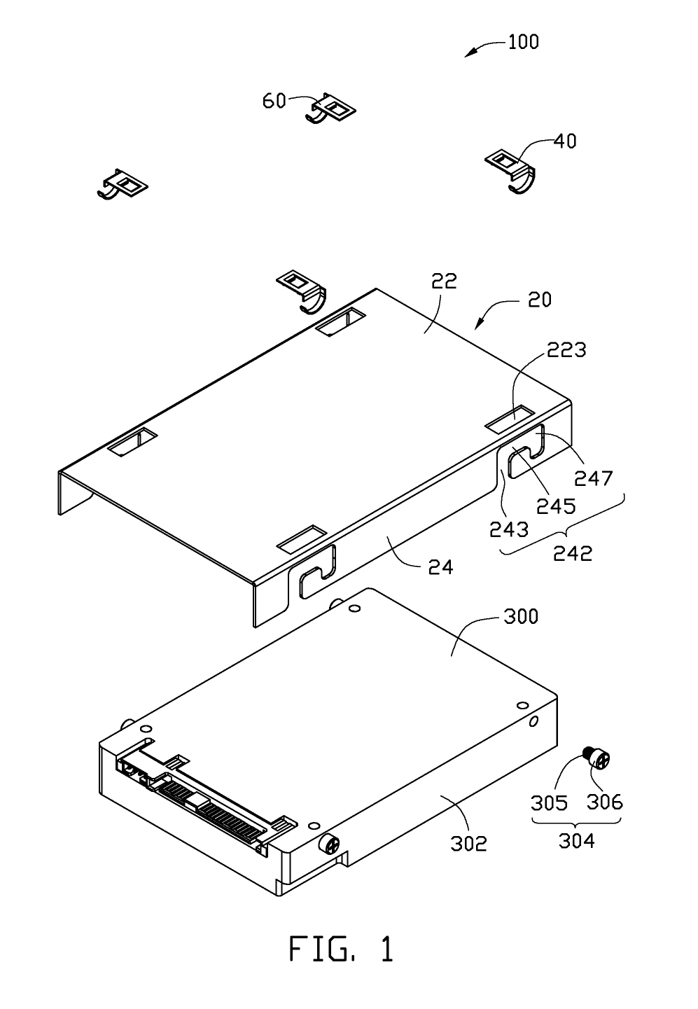

FIG. 1 shows an exemplary embodiment of an electronic device. The electronic device includes a hard disk drive (HDD) 300 and a mounting apparatus 100 for mounting the HDD 300 on a rack of a computer (not shown). The mounting apparatus 100 includes a bracket 20, two resilient first positioning members 40, and two resilient second positioning members 60.

The HDD 300 includes two opposite sidewalls 302. Two spaced fasteners 304 are respectively mounted to front and rear ends of each sidewall 302. Each fastener 304 includes a connecting pole 305 connected to the sidewall 302 in a substantially perpendicular manner and a mounting pole 306 protruding from a distal end of the connecting pole 305. In the embodiment, the fasteners 304 are screws.

The bracket 20 includes two opposite and rectangular side plates 24 and a top plate 22 connected between top sides of the side plates 24. Two spaced latching slots 242 are respectively defined in front and rear ends of each side plate 24. Each latching slot 242 includes an opening 243 extending up and through a bottom side of the corresponding side plate 24, a guiding portion 245 perpendicularly extending forward from a top end of the opening 243, and a notch 247 perpendicularly extending down from a distal end of the guiding portion 245 opposite to the opening 243. The top plate 22 defines four positioning slots 223 respectively adjacent to the latching slots 242, and an extension direction of each positioning slot 223 is parallel to the side plates 24.

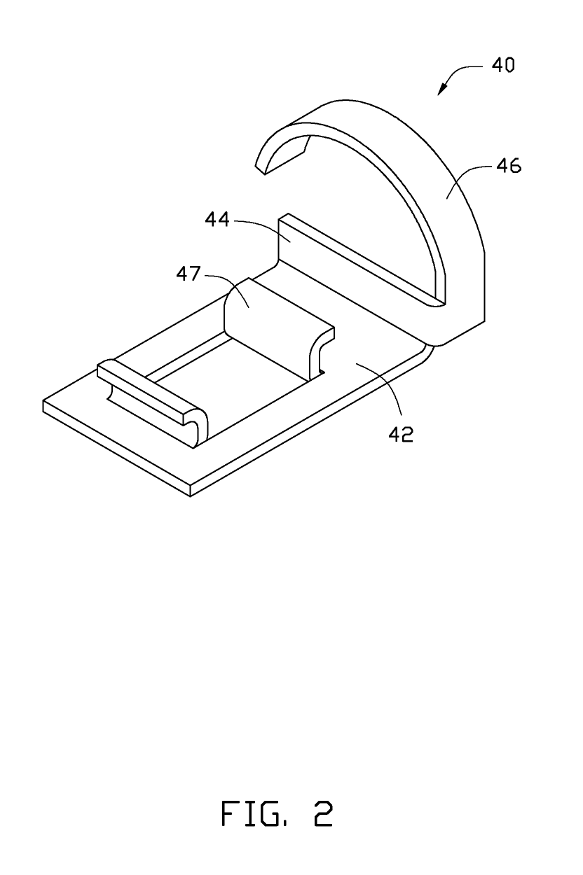

FIG. 2 shows the first positioning members 40 of the embodiment. Each first positioning member 40 includes a rectangular first sliding plate 42, a first end plate 44 perpendicularly extending down from a left end of the first sliding plate 42. As well as a substantially C-shaped and resilient first engaging piece 46 extending down from a front end of the first end plate 44 to a rear end of the first end plate 44. Two opposite hooks 47 extend down from the first sliding plate 42, with one of the hooks 47 located between the first end plate 44 and the other hook 47.

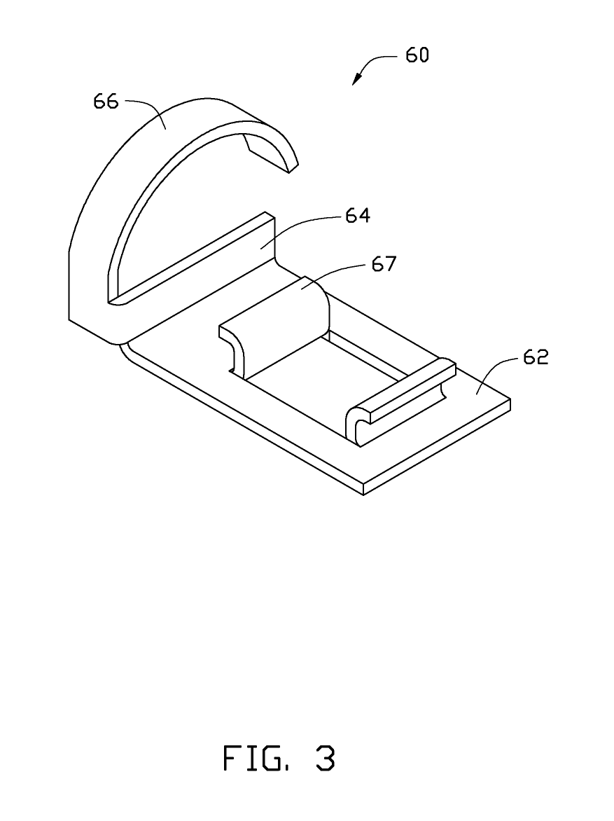

FIG. 3 shows that each second positioning member 60 is mirrored with the corresponding first positioning member 40 Each positioning member 60 includes a rectangular second sliding plate 62, a second end plate 64 perpendicularly extending down from a right end of the second sliding plate 62. As well as a substantially C-shaped and resilient second engaging piece 66 extending down from a front end of the second end plate 64 to a rear end of the second end plate 64. Two opposite hooks 67 extend down from the second sliding plate 62, with one of the hooks 67 located between the second end plate 64 and the other hook 67.

Each first and second positioning members 40 and 60 are made of resilient material, such as plastic or steel, for example.

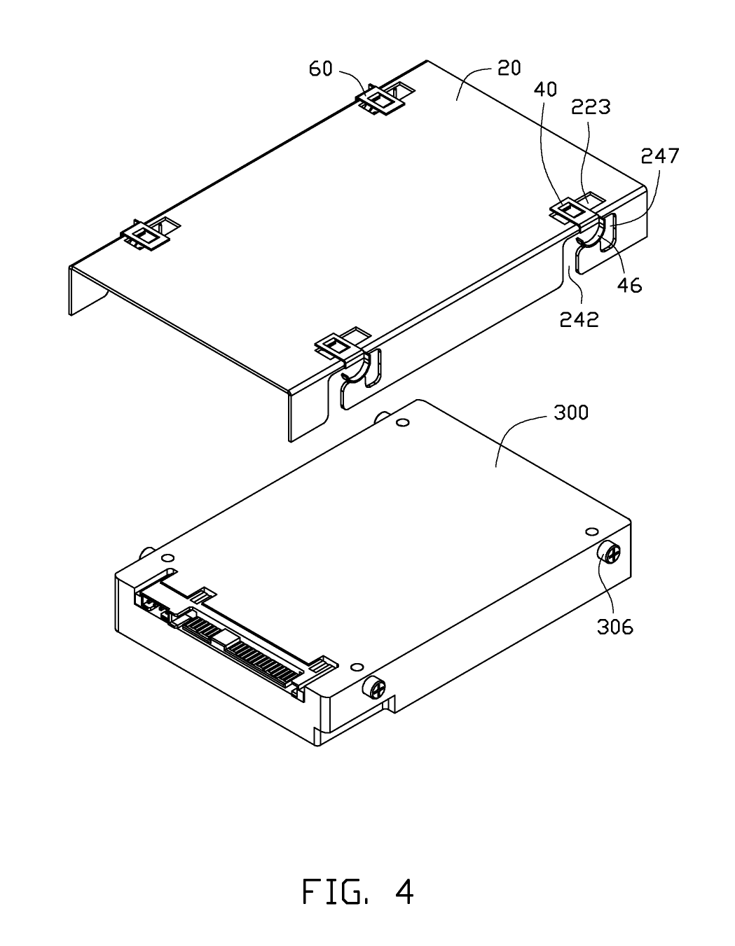

FIG. 4 shows that in assembly of the mounting apparatus 100, the hooks 47 of each first positioning member 40 are deformed toward each other and are inserted into the corresponding positioning slot 223 from a top of the top plate 22. In addition, each first positioning member 40 is located at a left side of the bracket 20. The hooks 47 are restored and slidably hook opposite long sidewalls bounding the corresponding positioning slot 223. The first engaging piece 46 of each first positioning member 40 is located at an outer side of the left side plate 24 and aligned with the guiding portion 245 of the corresponding latching slot 242. A distal end of the first engaging piece 46 faces and is located above the corresponding opening 243. The second positioning members 60 are mounted to the right side of the bracket 20 like the first positioning members 40. The second engaging piece 66 of each second positioning member 60 is located at an outer side of the right side plate 24 and aligned with the guiding portion 245 of the corresponding latching slot 242. A distal end of the second engaging piece 66 faces the corresponding opening 243.

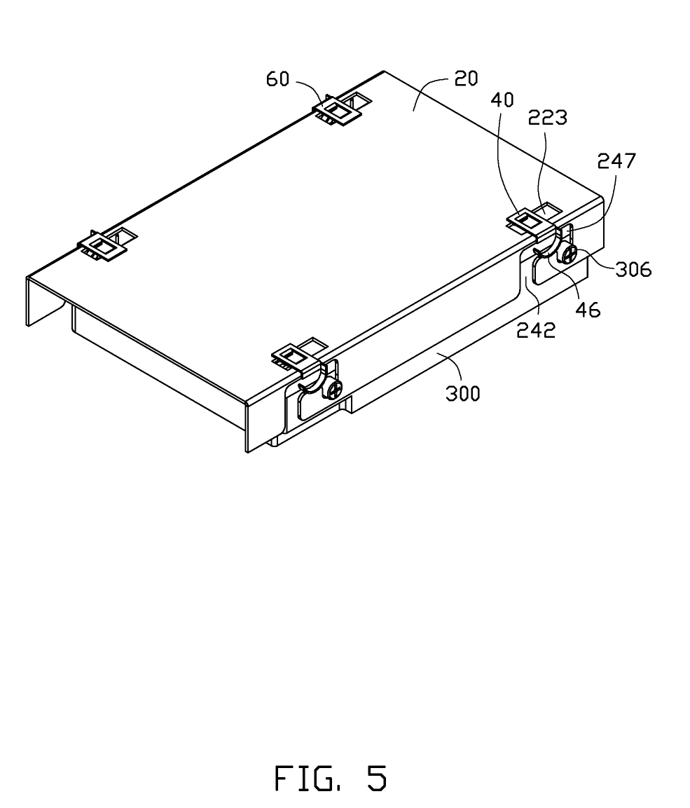

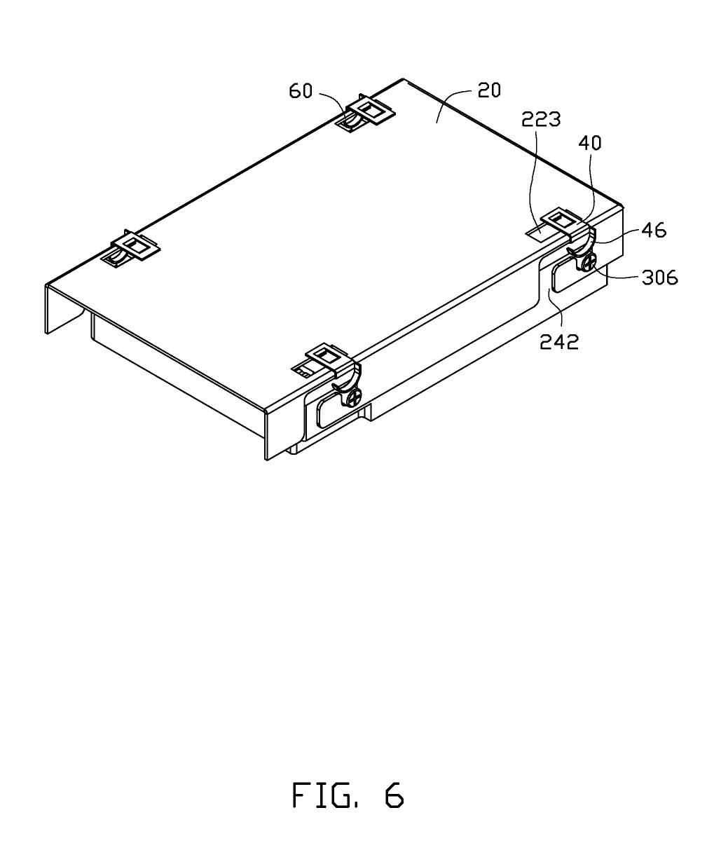

Referring to FIGS. 5 and 6, in assembly of the HDD 300 to the mounting apparatus 100, the first and second positioning members 40 and 60 are slid along the positioning slots 223 toward the corresponding openings 243, until the first and second engaging pieces 46 and 66 are respectively located above the corresponding openings 243. The HDD 300 is placed below the bracket 20, with the mounting poles 306 of the fasteners 304 respectively aligning with the openings 243. The HDD 300 is moved up, to allow the mounting poles 306 to be respectively inserted into the openings 243. The mounting poles 306 respectively abut the first and second engaging pieces 46 and 66, deforming the first and second engaging pieces 46 and 66, until the mounting poles 306 respectively align with the guiding portions 245. The HDD 300 is moved forward along the corresponding guiding portions 245. The mounting poles 306 are respectively slid into the notches 247, and the first and second engaging pieces 46 and 66 are restored. The first and second positioning members 40 and 60 are slid forward along the corresponding positioning slots 223, until the first and second engaging pieces 46 and 66 resiliently press the corresponding mounting poles 306, to retain the mounting poles 306 in the notches 247.

To detach the HDD 300 from the bracket 20, the first and second positioning members 40 and 60 are slid rearward, to allow the first and second engaging pieces 46 and 66 to disengage from the mounting poles 306. The HDD 300 is moved up, until the mounting poles 306 respectively align with the corresponding guiding portions 245. The HDD 300 is slid rearward, and the mounting poles 306 are slid into the guiding portions 245, to allow the mounting poles 306 to disengage from the notches 247. The mounting poles 306 respectively abut the first and second engaging pieces 46 and 66, to deform the first and second engaging pieces 46 and 66, until the mounting poles 306 pass through the first and second pieces 46 and align with the openings 243. Thereby, the HDD 300 can be moved down and thus be detached from the bracket 20.

Even though numerous characteristics and advantages of the embodiments have been set forth in the foregoing description, together with details of the structure and function of the embodiments, the present disclosure is illustrative only, and changes may be made in details, especially in the matters of shape, size, and arrangement of parts within the principles of the embodiments to the full extent indicated by the broad general meaning of the terms in which the appended claims are expressed.

What is claimed is:

1. A mounting apparatus for a hard disk drive with a first and a second mounting poles respectively protruding from two opposite sidewalls of the hard disk drive, the mounting apparatus comprising:
a bracket comprising a first side plate, wherein a first latching slot is defined in the first side plate, the first latching slot comprises an opening extending through a bottom side of the first side plate, a notch, and a guiding portion connected between the opening and the notch; and
a first positioning member comprising a resilient first engaging piece, wherein the first positioning member is movably installed to the bracket, the first engaging piece faces the first latching slot;
wherein when mounting the hard disk drive, the first mounting pole is inserted into the first latching slot from the opening, and abuts the first engaging piece to deform the first engaging piece, until the first mounting pole is received in the notch along the guiding portion, and the first engaging piece is restored, the first positioning member is moved toward the first mounting pole to allow the first engaging piece to abut the first mounting pole.

2. The mounting apparatus of claim 1, further comprising a second positioning member, wherein the bracket further comprises a second side plate opposite to the first side plate, the second side plate defines a second latching slot same with the first latching slot, the second positioning member comprises a resilient second engaging piece, the second positioning member is movably installed to the bracket with the second engaging piece facing the second latching slot; when mounting the hard disk drive, the second mounting pole is inserted into the second latching slot, and abuts the second engaging piece to deform the second engaging piece, until the second mounting pole is received in the notch along the guiding portion of the second latching slot, the second positioning member is moved, to allow the second engaging piece to abut the second mounting pole.

3. The mounting apparatus of claim 2, wherein the bracket further comprises a top plate connected between top sides of the first and second side plates, the first and second positioning members installed to the top plate and respectively adjacent to the first and second side plates.

4. The mounting apparatus of claim 3, wherein the top plate defines first and second positioning slots respectively adjacent to the first and second latching slots, the first and second positioning slots are parallel to the first and second side plates, each of the first and second positioning members further comprise a sliding plate slidable along the corresponding positioning slot, the first engaging piece is formed on an end of the corresponding sliding plate adjacent to the first latching slot, the second engaging piece is formed on an end of the corresponding sliding plate adjacent to the second latching slot.

5. The mounting apparatus of claim 4, wherein two hooks protrude from each sliding plate and are inserted in the corresponding positioning slot, the hooks of each sliding plate are slidably abutted two opposite sidewalls bounding the corresponding positioning slot.

6. The mounting apparatus of claim 4, wherein the first and second engaging pieces are substantially C-shaped.

7. The mounting apparatus of claim 6, wherein the first engaging piece extends from a first side of the corresponding sliding plate adjacent to the corresponding notch toward a second side of the corresponding sliding plate adjacent to the corresponding opening.

8. The mounting apparatus of claim 6, wherein the second engaging piece extends from a first side of the corresponding sliding plate adjacent to the corresponding notch toward a second side of the corresponding sliding plate adjacent to the corresponding opening.

9. The mounting apparatus of claim 2, wherein the first and second positioning members are made of resilient material.

10. An electronic device, comprising:
a hard disk drive comprising two opposite sidewalls, and a first and a second mounting poles respectively protruding from the sidewalls;
a bracket comprising a first side plate, wherein a first latching slot is defined in the first side plate, the first latching slot comprises an opening extending through a bottom side of the first side plate, a notch, and a guiding portion connected between the opening and the notch; and
a first positioning member comprising a resilient first engaging piece, wherein the first positioning member is movably installed to the bracket, the first engaging piece faces the first latching slot;
wherein when mounting the hard disk drive, the first mounting pole is inserted into the first latching slot from the opening, to abut the first engaging piece and deform the first engaging piece, until the first mounting pole is received in the notch along the guiding portion, and the first engaging piece is restored, the first positioning member is moved toward the first mounting pole, to allow the first engaging piece to abut the first mounting pole.

11. The electronic device of claim 10, further comprising a second positioning member, wherein the bracket further comprises a second side plate opposite to the first side plate, the second side plate defines a second latching slot same with the first latching slot in structure, the second positioning member comprises a resilient second engaging piece, the second positioning member is movably installed to the bracket, and the second engaging piece faces the second latching slot; when mounting the hard disk drive, the second mounting pole is inserted into the second latching slot, to abut the second engaging piece and deform the second engaging piece, until the second mounting pole is received in the notch along the guiding portion of the second latching slot, the second positioning member is moved, to allow the second engaging piece to abut the second mounting pole.

12. The electronic device of claim 11, wherein the bracket further comprises a top plate connected between top sides of the first and second side plates, the first and second positioning members are installed to the top plate and respectively adjacent to the first and second side plates.

13. The electronic device of claim 12, wherein the top plate defines two positioning slots respectively adjacent to the first and second latching slots, the first and second positioning slots are parallel to the first and second side plates, each of the first and second positioning members further comprises a sliding plate slidable along the corresponding positioning slot, the first engaging piece is formed on an end of the corresponding sliding plate adjacent to the first latching slot, the second engaging piece is formed on an end of the corresponding sliding plate adjacent to the second latching slot.

14. The electronic device of claim 13, wherein two hooks protrude from each sliding plate and are inserted in the corresponding positioning slot, the hooks of each sliding plate respectively slidably hook two opposite sidewalls bounding the corresponding positioning slot.

15. An electronic device, comprising:
a bracket comprising two opposite side plates, wherein each side plate defines a latching slot, the latching slot comprises an opening extending through a bottom side of the first side plate and extending up in the side plate, a guiding portion extending forward from a top end of the opening, a notch extending down from a front end of the guiding portion;
a first positioning member slidably mounted to the bracket in a fore-and-aft direction, and comprising a resilient first engaging piece located at a side of one of the side plates and facing the corresponding latching slot; and
a second positioning member slidably mounted to the bracket in the fore-and-aft direction, and comprising a resilient second engaging piece located at a side of the other side plates and facing the corresponding latching slot.

16. The electronic device of claim 15, wherein the first and second engaging pieces are arced down to form a substantial C-shape.

17. The electronic device of claim 15, wherein the bracket further comprises a top plate connected between top sides of the side plates, the top plate defines two positioning slots respectively adjacent to the latching slots of the side plate and extending in the fore-and-aft direction, each of the first and second positioning members further comprises a sliding plate mounted to the top plate and slidable along the corresponding positioning slot.

18. The electronic device of claim 17, wherein the first and second engaging pieces are arced down to form a substantial C-shape.

19. The electronic device of claim 18, wherein the first and second engaging pieces are mirrored to each other.

20. The electronic device of claim 19, wherein each of the first and second engaging pieces extends from a front end toward a rear end of an outer side of the corresponding sliding plate.
